(19) United States
(12) Patent Application Publication
(10) Pub. No.: US 2025/0393427 A1
(43) Pub. Date: Dec. 25, 2025

(54) LIGHT EMITTING DISPLAY DEVICE AND ELECTRONIC DEVICE INCLUDING THE SAME

(71) Applicant: Samsung Display Co., Ltd., Yongin-Si (KR)

(72) Inventors: Sun Kwun SON, Yongin-si (KR); KYUNGHO KIM, Yongin-si (KR); Dong Hee SHIN, Yongin-si (KR)

(21) Appl. No.: 19/045,548

(22) Filed: Feb. 5, 2025

(30) Foreign Application Priority Data
Jun. 25, 2024 (KR) 10-2024-0083174
Jul. 16, 2024 (KR) 10-2024-0093858

(51) Int. Cl. H10K 59/131

(52) U.S. Cl. CPC H10K 59/1315

(57) ABSTRACT

A light emitting display device according to an embodiment includes a substrate including a display area in which pixels are arranged and a non-display area adjacent to the display area, a first power line extending in a first direction in the display area, a second power line extending in a second direction intersecting the first direction in the display area, a resistance reduction layer disposed in the non-display area, and a common electrode disposed across the display area and the non-display area, and connected to the resistance reduction layer in the non-display area. The second power line may be connected to the resistance reduction layer in the non-display area and is connected to the first power line in the display area.

### CROSS-REFERENCE TO RELATED APPLICATIONS

This application claims priority to, under 35 U.S.C. § 119, and the benefit of Korean Patent Application No. 10-2024-0093858 filed on Jul. 16, 2024, and Korean Patent Application No. 10-2024-0083174 filed on Jun. 25, 2024, in the Korean Intellectual Property Office, the entire contents of which are incorporated herein by reference.

### BACKGROUND

### 1. Field

This disclosure relates to a display device and an electronic device including the same, and more specifically to a light emitting display device including light emitting diodes.

### 2. Description of the Related Art

As display devices, light emitting display devices that display images by controlling a luminance of light emitting elements and liquid crystal displays that display images by controlling a transmittance of a liquid crystal layer have been widely used. Unlike the liquid crystal display, the light emitting display device does not require a separate light source such as a backlight, thereby reducing a thickness and a weight of the display device. In addition, the light emitting display device provides high-quality characteristics such as low power consumption, high luminance, and high reaction speed.

The light emitting display device may include a display area corresponding to a screen for displaying an image, and pixels may be arranged in the display area. Each pixel may include a light emitting element and a pixel circuit part that drives the light emitting element. The pixel circuit part may include transistors and capacitors.

In the light emitting display device, the light emitting elements may include a common electrode to which a common voltage is applied. As light emitting display devices become larger, it may be difficult to apply the common voltage uniformly across the entire display area due to a voltage drop caused by resistance of the common electrode.

### SUMMARY

Embodiments of the present disclosure provide a light emitting display device that uniformly applies a common voltage across the entire display area.

According to an embodiment, alight emitting display device includes a substrate including a display area in which pixels are arranged and a non-display area adjacent to the display area, a first power line extending in a first direction in the display area, a second power line extending in a second direction intersecting the first direction in the display area, a resistance reduction layer disposed in the non-display area, and a common electrode disposed across the display area and the non-display area, and connected to the resistance reduction layer in the non-display area. The second power line may be connected to the resistance reduction layer in the non-display area and is connected to the first power line in the display area.

The second power line may extend from the resistance reduction layer in the second direction.

The common electrode may be connected to the second power line in the display area.

The second power line and the resistance reduction layer may be integrally formed.

The light emitting display device may further include an insulating layer disposed between the first power line and the second power line. The second power line may be connected to the first power line through a contact hole formed in the insulating layer.

The light emitting display device may further include a connection electrode disposed on the insulating layer and connected to the first power line through a contact hole formed in the insulating layer. The common electrode may be connected to the connection electrode.

The insulating layer may include an inorganic insulating layer disposed on the first power line and an organic insulating layer disposed on the inorganic insulating layer.

The light emitting display device may further include a pixel electrode disposed on the insulating layer. The resistance reduction layer and the second power line may be disposed on a same layer as the pixel electrode.

The light emitting display device may further include an insulating layer disposed on the second power line, and an intermediate layer disposed on the insulating layer and including a light emitting layer. The common electrode may be connected to the second power line through a contact hole formed in the light emitting layer and the insulating layer in the display area.

The common electrode may be connected to the resistance reduction layer through a contact hole formed in the insulating layer in the non-display area.

The first power line and the second power line may transmit a common voltage.

The light emitting display device may further include a driving voltage line extending in the second direction in the display area and transmitting the driving voltage. The driving voltage line may be disposed on a same layer as the second power line.

The non-display area may include a dummy pixel region disposed between the resistance reduction layer and the display area. The second power line may extend across the dummy pixel region in the second direction.

According to an embodiment, alight emitting display device includes a substrate including a display area and a non-display area, a first common voltage line extending in a first direction in the display area and transmitting a common voltage, a second common voltage line extending in a second direction intersecting the first direction above the first common voltage line, connected to the first common voltage line, and transmitting the common voltage, a pixel electrode disposed in the display area, a resistance reduction layer disposed in the non-display area, disposed on a same layer as the second common voltage line, and connected to the second common voltage line, and a common electrode disposed on the second common voltage line and the resistance reduction layer, connected to the second common voltage line in the display area, and connected to the resistance reduction layer in the non-display area.

The second common voltage line and the resistance reduction layer may be disposed on a same layer as the pixel electrode.

The light emitting display device may further include a connection electrode disposed on a same layer as the second common voltage line and overlapping the first common voltage line. The common electrode may be connected to the first common voltage line through the connection electrode.

The light emitting display device may further include a first driving voltage line extending in the first direction in the display area and transmitting a driving voltage, and a second driving voltage line extending in the second direction above the first driving voltage line, disposed on a same layer as the second common voltage line, and transmitting the driving voltage.

The light emitting display device may further include a connection electrode disposed on a same layer as the first common voltage line. The second driving voltage line may be connected to the first common voltage line through the connection electrode.

The non-display area may include a dummy pixel region disposed between the resistance reduction layer and the display area. The second common voltage line may extend across the dummy pixel region in the second direction.

The light emitting display device may further include an intermediate layer disposed between the pixel electrode and the common electrode and including a light emitting layer. The common electrode may be connected to the second common voltage line through a contact hole formed in the light emitting layer.

According to an embodiment, an electronic device includes a processor providing input image data, and a display device displaying an image based on the input image data. The display device includes a substrate including a display area in which pixels are arranged and a non-display area adjacent to the display area, a first power line extending in a first direction in the display area, a second power line extending in a second direction intersecting the first direction in the display area, a resistance reduction layer disposed in the non-display area, and a common electrode disposed across the display area and the non-display area, and connected to the resistance reduction layer in the non-display area. The second power line may be connected to the resistance reduction layer in the non-display area and is connected to the first power line in the display area.

According to embodiments, the light emitting display device may uniformly apply the common voltage across the entire display area. Features of the present invention are not limited to the object features mentioned above, and other technical objects features not mentioned above will be clearly understood by those skilled in the art from the description below.

### BRIEF DESCRIPTION OF THE DRAWINGS

FIG. 1 is a schematic top plan view of a light emitting display device according to an embodiment.

FIG. 2 is a circuit diagram of a pixel of a light emitting display device according to an embodiment.

FIG. 3 is a top plan view of a pixel area of a light emitting display device according to an embodiment.

FIG. 4 is a cross-sectional view taken along a line A-A′ in FIG. 3.

FIG. 5 is a cross-sectional view taken along a line B-B′ in FIG. 3.

FIG. 6 is a cross-sectional view taken along a line C-C′ in FIG. 3.

FIG. 7, FIG. 8, FIG. 9, FIG. 10, FIG. 11, and FIG. 12 are top plan views illustrating layers included in a light emitting display device of FIG. 3 according to manufacturing steps.

FIG. 13 is a diagram showing a voltage drop measurement position in a light emitting display device according to an embodiment and a comparative example.

FIG. 14 is a schematic cross-sectional view of a display area in a light emitting display device according to an embodiment.

FIG. 15 is a block diagram of an electronic device according to an embodiment.

FIG. 16 shows schematic diagrams of electronic devices according to various embodiments.

### DETAILED DESCRIPTION

The embodiments of the present disclosure will be described in detail with reference to the accompanying drawings. As those skilled in the art may realize, the described embodiments may be modified in various different ways, all of which, however, are not departing from the spirit or scope of the present disclosure.

It should be understood that when an element such as a layer, film, region, or substrate is referred to as being “on” another element, it may be directly on the other element or intervening elements may also be present. In contrast, when an element is referred to as being “directly on” another element, there are no intervening elements present therebetween.

In the present disclosure, unless stated to the contrary, the word “comprise” and its variations such as “comprises” and “comprising” should be understood to imply the inclusion of stated elements but not the exclusion of any other elements.

When a part is stated to be “connected” to another part, it will be understood that the part may not only be “directly connected” to the other part, but also be “indirectly connected” to the other part through a third part. It also includes that the part may be connected to the other part physically or electrically. It may encompass a case where parts, referred to by different names due to their position or functions but integral in nature, may be connected to each other.

When the terms “x,” “y,” and “z” are used in the drawings, “x” may represent a first direction, “y” may represent a second direction that is perpendicular to the first direction, and “z” may represent a third direction that is perpendicular to the first direction and the second direction. The first direction x, the second direction y, and the third direction z may correspond to a horizontal direction, a vertical direction, and a thickness direction of the display device, respectively.

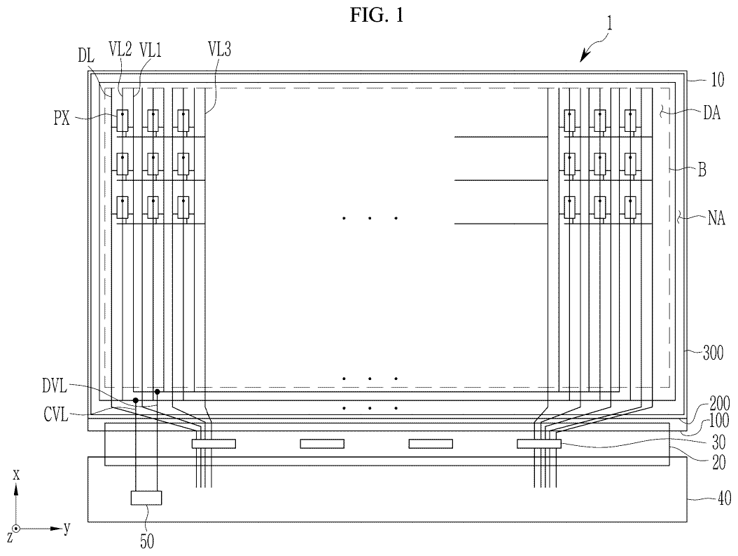

FIG. 1 is a schematic top plan view of a light emitting display device according to an embodiment.

Referring to FIG. 1, a light emitting display device 1 (hereinafter, also simply referred to as “a display device”) may include a display panel 10, a flexible printed circuit film 20, a driver IC chip 30, a printed circuit board (PCB) 40, a power module 50, etc.

The display panel 10 may include a display area DA corresponding to a screen that displays an image. The display panel 10 may include a non-display area NA in which circuits and wires for generating or transmitting various signals to be applied to the display area DA are arranged. The non-display area NA may be adjacent to the display area DA and may surround the display area DA. The non-display area NA may also be referred to as a peripheral area. In FIG. 1, the inner and outer regions for a boundary line B may be the display area DA and the non-display area NA, respectively.

The display panel 10 may include a display unit 100 and a color conversion unit 200. The display unit 100 and the color conversion unit 200 may be bonded together by a sealant 300 positioned around the edge of the display panel 10. The color conversion unit 200 may overlap the display unit 100 entirely, but the display unit 100 may include a region not covered by the color conversion unit 200 where the flexible printed circuit film 20 is attached to the display unit 100. The display unit 100 may include a pad part (not shown) which receives a signal or a power from the flexible printed circuit film 20.

In the region where the pad part is positioned, such as the bottom of the display panel 10, the color conversion unit 200 may be formed shorter than the display unit 100 to make the pad part exposed to the outside. Each of the display unit 100 and the color conversion unit 200 may include regions corresponding to the display area DA and the non-display area NA of the display panel 10.

In the display area DA of the display panel 10, pixels PX may be arranged in a matrix. Additionally, a data line DL that transmits a data voltage V_{DATA}, a driving voltage line VL1 that transmits a driving voltage EL_{VDD}, a common voltage line VL2 that transmits a common voltage EL_{VSS}, and an initialization voltage line VL3 that transmits an initialization voltage V_{INT} may be positioned in the display area DA. The driving voltage line VL1, the common voltage line VL2, and the initialization voltage line VL3 may be extended in the first direction x. Each pixel PX may receive the data voltage V_{DATA}, the driving voltage EL_{VDD}, the common voltage EL_{VSS}, and the initialization voltage V_{INT} from the data line DL, the driving voltage line VL1, the common voltage line VL2, and the initialization voltage line VL3, respectively. The driving voltage EL_{VDD} and the common voltage EL_{VSS} may be referred to as power voltages applied to each pixel PX, and the driving voltage line VL1 and the common voltage line VL2 that transmit the driving voltage EL_{VDD} and the common voltage EL_{VSS} may be referred to as power voltage lines. The driving voltage EL_{VDD} may be a higher voltage than the common voltage EL_{VSS}. The driving voltage EL_{VDD} may be referred to as a first power voltage or a high-potential power voltage. The common voltage EL_{VSS} may be referred to as a second power voltage or a low-potential power voltage. The power voltage line may include a first power line extending in the first direction x and a second power line extending in the second direction y. The first power line and the second power line may be connected in the display area DA and form a mesh structure.

In the non-display area NA of the display panel 10, gate drivers (not shown) may be positioned on either side of the display area DA. The gate driver may be integrated into the non-display area NA. The pixels PX may receive a gate signal (also referred to as a scan signal) generated from the gate driver and receive a data voltage V_{DATA} at a predetermined timing.

A driving voltage transmitting line DVL connected to the driving voltage lines VL1, a common voltage transmitting line CVL connected to the common voltage lines VL2, etc. may be positioned in the non-display area NA of the display panel 10. Each of the driving voltage transmitting line DVL and the common voltage transmitting line CVL may include a portion extending approximately in the first direction x and a portion extending approximately in the second direction y, respectively. The common voltage transmitting line CVL may be positioned to surround the display area DA. The common voltage lines VL2 may be connected to the common voltage transmitting lines CVL at the lower and upper sides of the display area DA, thereby supplying the common voltage EL_{VSS} uniformly throughout the entire display area DA.

The flexible printed circuit film 20 may have a first end connected or bonded to the display unit 100 of the display panel 10, and a second end connected or bonded to the printed circuit board (PCB) 40. The driver IC chip 30 including the data driver that applies the data voltage V_{DATA} to the data line DL may be positioned on the flexible printed circuit film 20.

The power module 50 that generates the power voltages such as the driving voltage EL_{VDD} and the common voltage EL_{VSS} may be positioned on the printed circuit board (PCB) 40. The power module 50 may be provided in an IC chip form. The driving voltage EL_{VDD}, the common voltage EL_{VSS}, etc. may also be output through the driver IC chip 30. A signal controller (not shown) that controls the data driver and the gate driver may be positioned on the printed circuit board (PCB) 40.

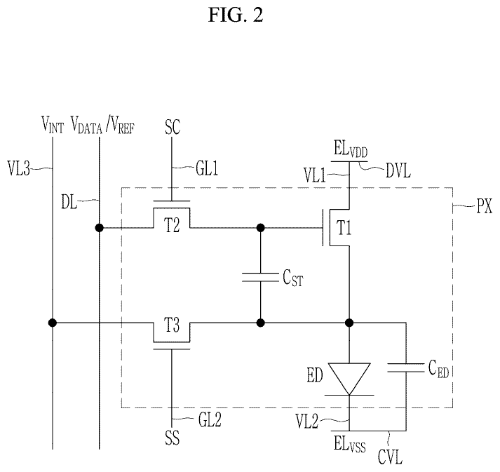

FIG. 2 is a circuit diagram of a pixel of a light emitting display device according to an embodiment.

Referring to FIG. 2, a pixel PX may include first, second, and third transistors T1, T2, and T3, a storage capacitor C_{ST}, and a light emitting element ED. The pixel PX may further include a light emitting element capacitor C_{ED} connected to both terminals of the light emitting element ED. The light emitting element ED may be an organic or inorganic light emitting diode. The first, second, and third transistors T1, T2, and T3 may be n-type transistors, and at least some of them may be p-type transistors. Each of the first, second, and third transistors T1, T2, and T3 may include a gate electrode, a first electrode, and a second electrode. One of the first electrode and the second electrode may be a source electrode and the other may be a drain electrode.

The gate electrode of the first transistor T1 may be connected to the first electrode of the storage capacitor CST. The first electrode of the first transistor T1 may be connected to the driving voltage line VL1 that transmits the driving voltage EL_{VDD}. The second electrode of the first transistor T1 may be connected to the first electrode (e.g., an anode) of the light emitting element ED and the second electrode of the storage capacitor C_{ST}. The storage capacitor C_{ST} may receive and store the data voltage V_{DATA} in response to the switching operation of the second transistor T2, and the transistor T1 may supply the driving current to the light emitting element ED in response to the voltage stored in the storage capacitor C_{ST}. The first transistor T1 may be referred to as a driving transistor.

The gate electrode of the second transistor T2 may be connected to a first gate line GL1, which transmits a first scan signal SC. The first electrode of the second transistor T2 may be connected to the data line DL, which may transmit the data voltage V_{DATA} or the reference voltage V_{REF}. The second electrode of the second transistor T2 may be connected to the first electrode of the storage capacitor C_{ST} and the gate electrode of the first transistor T1. The second transistor T2 may be turned on in response to the first scan signal SC and transmit the reference voltage V_{REF} or the data voltage V_{DATA} to the gate electrode of the first transistor T1.

The gate electrode of the third transistor T3 may be connected to the second gate line GL2, which transmits a second scan signal SS. The first electrode of the third transistor T3 may be connected to the initialization voltage line VL3, which transmits the initialization voltage V_{INT}. The second electrode of the third transistor T3 may be connected to the second electrode of the storage capacitor CST, the second electrode of the first transistor T1, and the anode. The third transistor T3 may be turned on in response to the second scan signal SS and transmit the initialization voltage V_{INT} to the first electrode of the light emitting element ED to initialize the voltage of the first electrode of the light emitting element ED (e.g., the anode).

The first electrode of the storage capacitor CST may be connected to the gate electrode of the first transistor T1. The second electrode of the storage capacitor CST may be connected to the second electrode of the third transistor T3 and the anode. The second electrode (e.g., a cathode) of the light emitting element ED may be connected to the common voltage line VL2, which transmits the common voltage EL_{VSS}. Each light emitting element ED may constitute one pixel PX. The first electrode and the second electrode of the light emitting element ED may be referred to as a pixel electrode and a common electrode, respectively.

The light emitting element ED may emit light of a luminance (gray) corresponding to the driving current generated by the first transistor T1. The light emitting element capacitor C_{ED} may keep the voltage at both terminals of the light emitting element ED constant, allowing the light emitting element ED to emit light with a constant luminance.

An example of an operation of the circuit shown in FIG. 2 during one frame is explained with an assumption that all of the transistors T1, T2, and T3 are n-type transistors.

At the beginning of a frame, during an initialization period, the common voltage EL_{VSS} in a high-level may be applied when the first scan signal SC and the second scan signal SS remain at a low level. This may prevent the current from flowing through the light emitting element ED, thereby preventing the light emitting element ED from emitting light. Additionally, the initialization voltage V_{INT} may be applied through the initialization voltage line VL3 to initialize the initialization voltage line VL3. Next, the high-level first scan signal SC and the high-level second scan signal SS are supplied, and the second transistor T2 and the third transistor T3 may be turned on. The reference voltage V_{REF} from the data line DL may be supplied to the gate electrode of the first transistor T1 and the first electrode of the storage capacitor C_{ST} through the turned-on second transistor T2. The initialization voltage V_{INT} may be supplied to the second electrode of the first transistor T1 and the anode through the turned-on third transistor T3. Accordingly, the anode may be initialized with the initialization voltage V_{INT} during the initialization period. The voltage difference (V_{REF}-V_{INT}) between the reference voltage V_{REF} and the initialization voltage V_{INT} may be stored in the storage capacitor C_{ST}.

In the sensing period, the high-level first scan signal SC and the high-level second scan signal SS may be maintained. At this time, the initialization voltage line VL3 may be disconnected from a supply source of the initialization voltage V_{INT} and may function as a sensing line. Through the turned-on second transistor T2, the gate electrode of the first transistor T1 and the first electrode of the storage capacitor CST may maintain the reference voltage V_{REF}. Accordingly, when the current flows from the first electrode of the first transistor T1 to the second electrode, and the voltage of the second electrode becomes “the reference voltage V_{REF}—the threshold voltage V_{TH},” the first transistor T1 may be turned off, and the initialization voltage line VL3 may be charged to “the reference voltage V_{REF}—the threshold voltage V_{TH}.”

Here, the threshold voltage V_{TH} represents the threshold voltage V_{TH} of the first transistor T1. The initialization voltage line VL3 charged to “the reference voltage V_{REF}—the threshold voltage V_{TH}” may be connected to an external circuit, and the external circuit may sense the voltage of the initialization voltage line VL3 to extract the threshold voltage V_{TH} of the first transistor T1. By generating a compensated data signal that reflects the characteristic information sensed during the sensing period, it is possible to compensate for the characteristic variations of the first transistor T1, which may be different for each pixel PX.

In a data input period, the high-level first scan signal SC may be supplied and the low-level second scan signal SS may be supplied. Through the turned-on second transistor T2, the data voltage V_{DATA} from the data line DL may be supplied to the gate electrode of the first transistor T1 and the first electrode of the storage capacitor C_{ST}. The data voltage V_{DATA} may have the compensated value based on the threshold voltage V_{TH} of the first transistor T1 which is sensed during the sensing period, thereby compensating the characteristic variation of the first transistor T1. When the data voltage V_{DATA} is applied, the second electrode of the first transistor T1 and the first electrode of the light emitting element ED may maintain the potential, which is almost unchanged as it was in the sensing period, due to the first transistor T1 being turned off.

In the light emitting period, the first transistor T1, which is turned on in response to data voltage V_{DATA} transmitted to the gate electrode of the first transistor, may generate the driving current corresponding to the data voltage V_{DATA}, and the light emitting element ED may emit light in response to the driving current. That is, the luminance of the light emitting element ED may be controlled by the driving current, flowing through the light emitting element ED, in response to the magnitude of the data voltage V_{DATA} applied to the pixel PX.

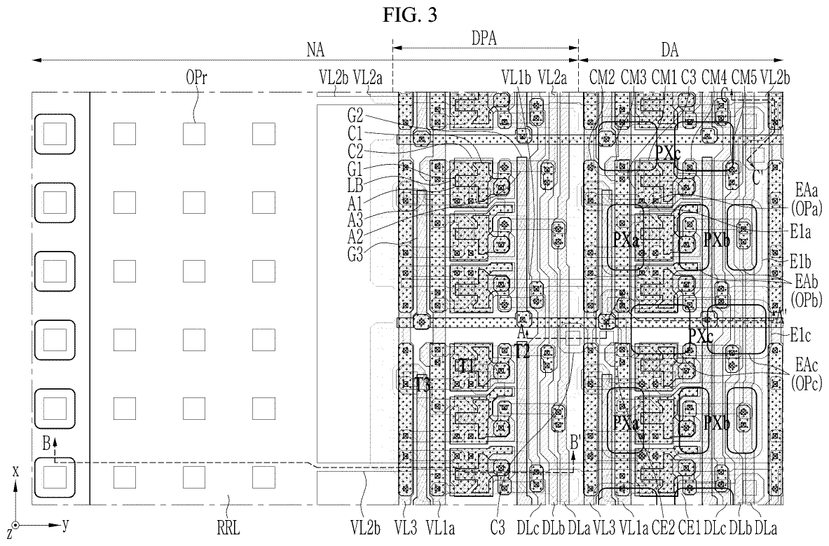

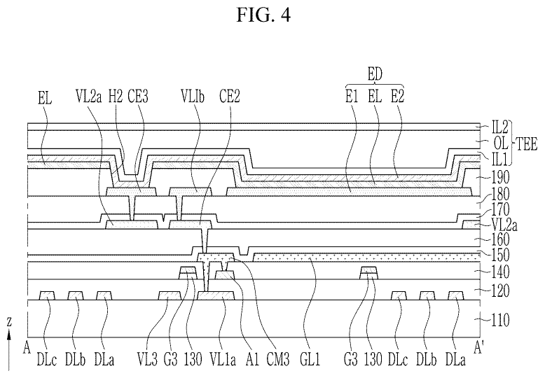

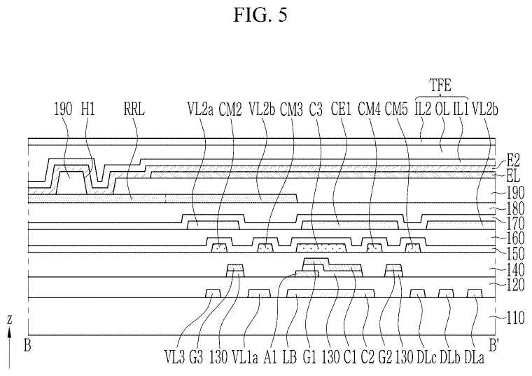

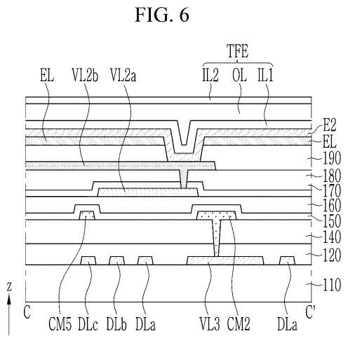

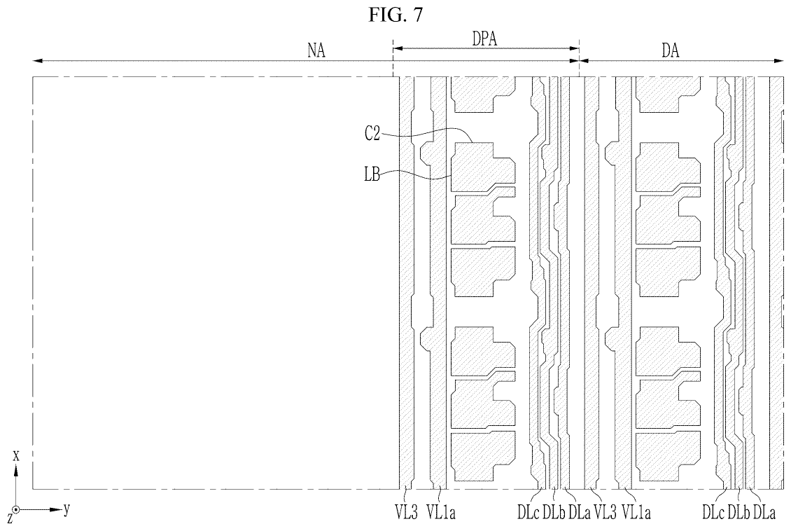

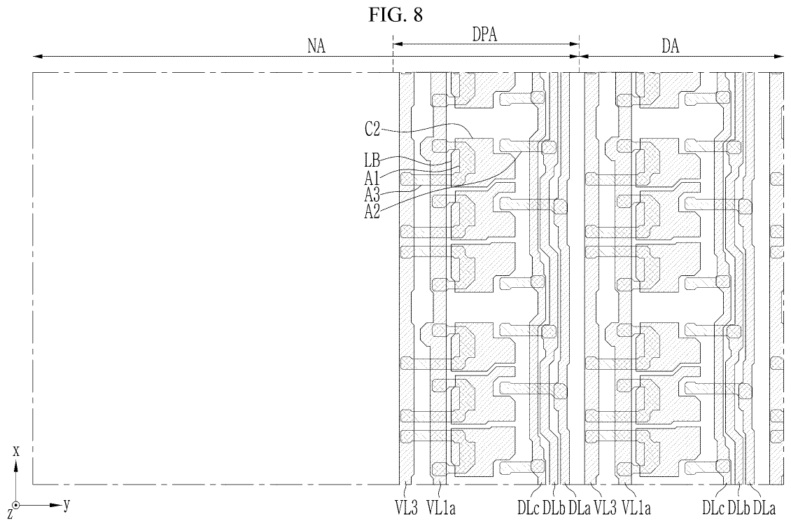

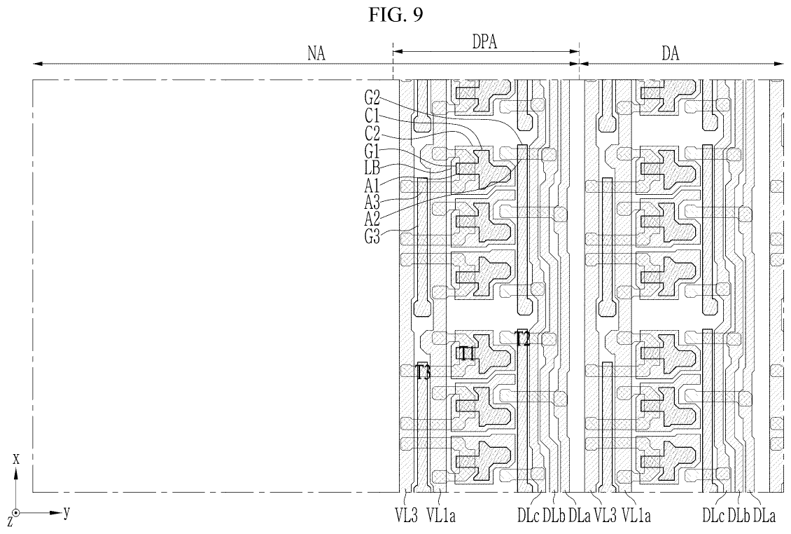

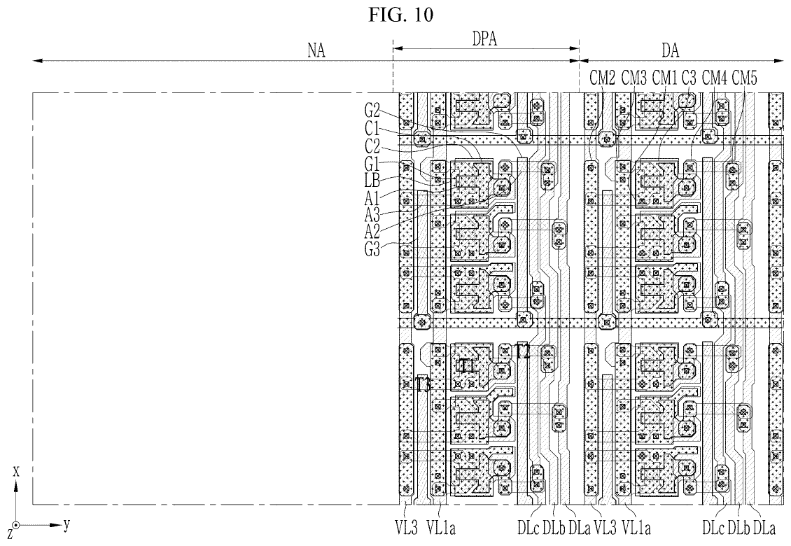

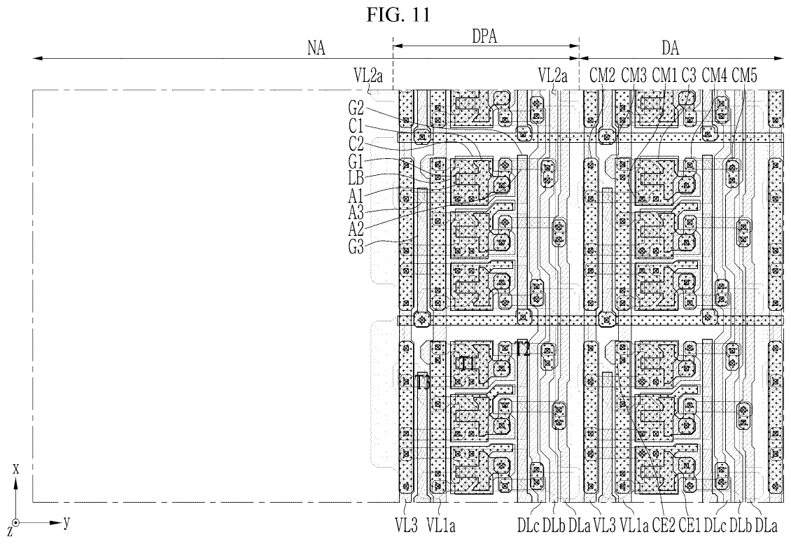

FIG. 3 is a top plan view of a pixel area of a light emitting display device according to an embodiment. FIG. 4 is a cross-sectional view taken along a line A-A′ in FIG. 3. FIG. 5 is a cross-sectional view taken along a line B-B′ in FIG. 3. FIG. 6 is a cross-sectional view taken along a line C-C′ in FIG. 3. FIG. 7, FIG. 8, FIG. 9, FIG. 10, FIG. 11, and FIG. 12 are top plan views illustrating layers included in a light emitting display device of FIG. 3 according to manufacturing steps.

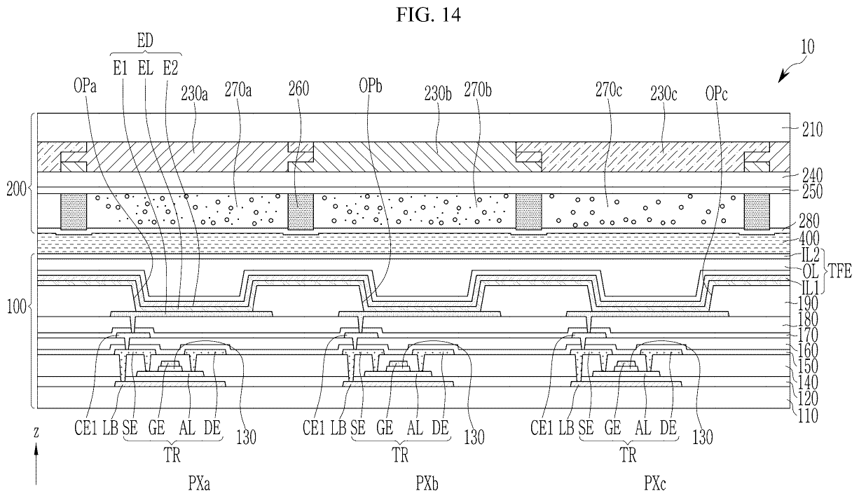

FIG. 3 illustrates pixels PXa, PXb, and PXc adjacent to a non-display area NA and wires connected thereto in a display panel 10 included in a light emitting display device according to an embodiment. The illustrated region may correspond to the area near a left border B in the display panel 10 illustrated in FIG. 1. FIG. 3 shows approximately three pixels PXa, PXb, and PXc and approximately three dummy pixels. Here, a dummy pixel may include a pixel circuit part and may not include a light emitting element. Therefore, FIG. 3 shows approximately six pixel circuit parts. In the display area DA, the pixels PXa, PXb, and PXc may be repeatedly arranged along the first direction x and the second direction y. The display unit 100 of the display panel 10 will be described in detail, and the color conversion unit 200 of the display panel 10 will be described later with reference to FIG. 14.

Referring to FIG. 3 to FIG. 12, the pixels PXa, PXb, and PXc may display different colors. That is, the pixels PXa, PXb, and PXc may include a first pixel PXa that displays a first color, a second pixel PXb that displays a second color different from the first color, and a third pixel PXc that displays a third color different from the first and second colors. One of the first, second, and third pixels PXa, PXb, and PXc may display red, another may display green, and the last one may display blue. For example, the first pixel PXa may display red, the second pixel PXb may display green, and the third pixel PXc may display blue, respectively. The first pixel PXa, the second pixel PXb, and the third pixel PXc may constitute a unit pixel. The first pixel PXa, the second pixel PXb and the third pixel PXc may be combined to display various colors. The first pixel PXa and the second pixel PXb may be adjacent to each other in the second direction y, and the third pixel PXc may be adjacent to the first and second pixels PXa and PXb in the first direction x. The arrangement of the first, second, and third pixels PXa, PXb, and PXc may be varied.

The display panel 10 may include first, second, and third light emitting regions EAa, EAb, and EAc, from which light is emitted from the first, second, and third pixels PXa, PXb, and PXc. For example, the red light may be emitted through the first light emitting region EAa, the green light may be emitted through the second light emitting region EAb, and the blue light may be emitted through the third light emitting region EAc. Each of the first, second, and third light emitting regions EAa, EAb, and EAc may have an approximately rectangular shape in a plan view. At least one of the first, second, and third light emitting regions EAa, EAb, and EAc may be divided into a plurality of sub-regions. For example, the second and third light emitting regions EAb and EAc may each be divided into two sub-regions.

In the non-display area NA, a dummy pixel region DPA where dummy pixels are positioned may be positioned in the region adjacent to the display area DA. The dummy pixel region DPA has the pixel circuit parts arranged similarly to the display area DA, but may not have the light emitting regions EAa, EAb, and EAc. Accordingly, the dummy pixels may not emit light, unlike the pixels PXa, PXb, and PXc. The dummy pixels may be formed to improve a process variation or a loading effect that may occur during the manufacturing process of the display panel 10. The dummy pixels may be formed to surround the display area DA.

The display unit 100 may include a substrate 110, first, second, and third transistors T1, T2, and T3 formed on the substrate 110, the storage capacitor CST, and the light emitting element ED connected to the first transistor T1. The first, second, and third transistors T1, T2, and T3 and the storage capacitor CST may form a pixel circuit part corresponding to one pixel PX. The display unit 100 may include a resistance reduction layer RRL formed on the substrate 110 in the non-display area NA. The region that overlaps the resistance reduction layer RRL may include circuit parts, such as the gate driver, below the resistance reduction layer RRL. More particularly, the circuit parts below the resistance reduction layer RRL may be formed below the fourth insulating layer 150. To avoid complicating the drawing, the circuit parts positioned below the resistance reduction layer RRL are not shown.

The substrate 110 may include a material having a rigid characteristic, such as glass, or a material having a flexible characteristic, such as plastic. For example, the substrate 110 may be a glass substrate. The substrate 110 may include a polymer material such as a polyimide, a polyamide, or a polyethylene terephthalate.

A first conductive layer, which may include first, second, and third data lines DLa, DLb, and DLc, a first driving voltage line VLla, initialization voltage lines VL3, second capacitor electrodes C2, light blocking layers LB, etc. may be positioned on the substrate 110

FIG. 7 shows the first conductive layer.

The first data line DLa may transmit the data voltage V_{DATA} to the first pixel PXa, the second data line DLb may transmit the data voltage V_{DATA} to the second pixel PXb, and the third data line DLc may transmit the data voltage V_{DATA} to the third pixel PXc. Each of the first, second, and third data lines DLa, DLb, and DLc may extend in the first direction x. The first, second, and third data lines DLa, DLb, and DLc may be placed adjacent to each other in the second direction y.

The first driving voltage line VLla may transmit the driving voltage EL_{VDD}, and the initialization voltage line VL3 may transmit the initialization voltage V_{INT}. Each of the first driving voltage line VLla and the initialization voltage line VL3 may extend in the first direction x. The first driving voltage line VLla may be connected to the driving voltage transmitting line DVL in the non-display area NA. The initialization voltage line VL3 may be connected to the initialization voltage transfer line (not shown) in the non-display area.

The initialization voltage line VL3, the first driving voltage line VLla, and the data lines DLa, DLb, and DLc may be repeatedly arranged along the second direction y. Accordingly, in the second direction y, the first driving voltage line VLla may be positioned between the initialization voltage line VL3 and the data lines DLa, DLb, and DLc, and the initialization voltage line VL3 may be positioned between the data lines DLa, DLb, and DLc and the first driving voltage line VLla. The relative arrangement of the first driving voltage lines VLla, the initialization voltage lines VL3, and the data lines DLa, DLb, and DLc may vary.

The second capacitor electrodes C2 may be positioned between the first driving voltage line VLla and the data lines DLa, DLb, and DLc. The second capacitor electrodes C2 may be the second electrode of the storage capacitor CST of each pixel PXa, PXb, and PXc.

The light blocking layers LB may be positioned between the first driving voltage line VLla and the data lines DLa, DLb, and DLc. The light blocking layers LB may block external light from reaching the first semiconductor layer A1 of the first transistor T1 of each pixel PXa, PXb, and PXc, thereby preventing the characteristic deterioration of the first semiconductor layer A1. The leakage current of the driving transistor, whose current characteristic is critical in the light emitting display device 1, may be controlled by the light blocking layers LB. The light blocking layer LB may function as an electrode that receives a specific voltage. Due to the light blocking layer LB being disposed under the first semiconductor layer A1 of the first transistor T1, a current variation ratio in a saturation region of the voltage-current characteristic graph of the first transistor T1 may decrease, thereby improving the characteristics of the driving transistor. The light blocking layer LB and the second capacitor electrode C2 in each pixel PXa, PXb, and PXc may be connected. The light blocking layer LB and the second capacitor electrode C2 may be formed integrally.

The components included in the first conductive layer may be formed using the same material in the same process. For example, a conductive layer may be deposited and patterned on the substrate 110 to form the data lines DLa, DLb, and DLc, the driving voltage line VL1, the initialization voltage line VL3, the second capacitor electrodes C2, and the light blocking layers LB. The first conductive layer may include a metal such as copper (Cu), aluminum (Al), titanium (Ti), molybdenum (Mo), or tungsten (W), and may be a single layer or multiple layers. For example, the first conductive layer may have a double-layer structure such as titanium (Ti)/copper (Cu).

A first insulating layer 120 may be disposed on the first conductive layer. The first insulating layer 120 may be referred to as a buffer layer. The first insulating layer 120 blocks impurities from the substrate 110 when the semiconductor layer is formed, thereby improving the characteristics of the semiconductor layer, and flattens the surface of the substrate 110, thereby reducing the stress on the semiconductor layer. The first insulating layer 120 may include an inorganic insulating material such as silicon nitride (SiNₓ), silicon oxide (SiOₓ), or silicon oxynitride (SiOₓN_{y}).

Semiconductor layers A1, A2, and A3 may be disposed on the first insulating layer 120. FIG. 8 illustrates a first conductive layer and a semiconductor layer.

The semiconductor layers A1, A2, and A3 may include a first semiconductor layer A1, which is a semiconductor layer of the first transistor T1, a second semiconductor layer A2, which is a semiconductor layer of the second transistor T2, and a third semiconductor layer A3, which is a semiconductor layer of the third transistor T3. Each of the semiconductor layers A1, A2, and A3 may include a first region, a second region, and a channel region between the first region and the second region. The first region of the first semiconductor layer A1 may be electrically connected to the driving voltage line VLL. The second region of the first semiconductor layer A1 may be electrically connected to the first electrode of the light emitting element ED. The channel region of the first semiconductor layer A1 may overlap the light blocking layer LB. The first region of the second semiconductor layer A2 may be electrically connected to the corresponding data lines DLa, DLb, and DLc. That is, the first region of the second semiconductor layer A2 of the first pixel PXa may be electrically connected to the first data line DLa, the first region of the second semiconductor layer A2 of the second pixel PXb may be electrically connected to the second data line DLb, and the first region of the second semiconductor layer A2 of the third pixel PXc may be electrically connected to the third data line DLc. The second region of the second semiconductor layer A2 may be electrically connected to the first capacitor electrode C1. The first region of the third semiconductor layer A3 may be electrically connected to the initialization voltage line VL3. The first semiconductor layer A1 has a shape that is roughly curved in a “¬” shape. The first semiconductor layer A1 may include a portion extending in the first direction x and a portion extending in the second direction y. The second and third semiconductor layers A2 and A3 may extend in the second direction y. The second region of the third semiconductor layer A3 may be connected to the second capacitor electrode C2. The second region of the first semiconductor layer A1 and the second region of the third semiconductor layer A3 may be connected. The first semiconductor layer A1 and the third semiconductor layer A3 may be integrally formed.

The semiconductor layers A1, A2, and A3 may be formed using the same material in the same process. The semiconductor layers A1, A2, and A3 may include an oxide semiconductor. For example, the semiconductor layers A1, A2, and A3 may include an oxide semiconductor, such as indium-gallium-zinc oxide (IGZO), including at least one of zinc (Zn), indium (In), gallium (Ga), tin (Sn), or a mixture thereof. The semiconductor layers A1, A2, and A3 may include polycrystalline silicon or amorphous silicon—for example, low-temperature polysilicon (LTPS).

A second insulating layer 130 may be disposed on the semiconductor layers A1, A2, and A3. The second insulating layer 130 may be called a gate insulating layer. The second insulating layer 130 may be formed in a region that overlaps the second conductive layer. The second insulating layer 130 may be formed to substantially cover the entire substrate 110. The second insulating layer 130 may be an inorganic insulating layer including an inorganic insulating material such as silicon oxide, silicon nitride, or silicon oxynitride, and may be a single layer or multiple layers.

A second conductive layer which may include gate electrodes G1, G2, and G3, and first capacitor electrodes C1 may be positioned on the second insulating layer 130. FIG. 9 illustrates the first conductive layer, the semiconductor layers, and the second conductive layer.

The gate electrodes G1, G2, and G3 may include a first gate electrode G1, which is a gate electrode of the first transistor T1, a second gate electrode G2, which is a gate electrode of the second transistor T2, and a third gate electrode G3, which is a gate electrode of the third transistor T3. The first, second, and third gate electrodes G1, G2, and G3 may overlap the channel regions of the corresponding first, second, and third semiconductor layers A1, A2, and A3, respectively. The second and third gate electrodes G2 and G3 may each extend in the first direction x.

The first capacitor electrodes C1 may overlap the second capacitor electrodes C2. The first capacitor electrode C1 may be the first electrode of the storage capacitor CST of each pixel PXa, PXb, and PXc. The first capacitor electrode C1 may be connected to the first gate electrode G1. The first capacitor electrodes C1 may be positioned between the first driving voltage line VLla and the data lines DLa, DLb, and DLc, and may be aligned in the first direction x. The first capacitor electrode C1 may be integrally formed with the first gate electrode G1. The first gate electrode G1 may protrude from the first capacitor electrode C1 in a direction parallel to the second direction y.

The components included in the second conductive layer may be formed using the same material in the same process. The second conductive layer may include a metal such as copper (Cu), aluminum (Al), titanium (Ti), molybdenum (Mo), or tungsten (W), and may be a single layer or multiple layers. For example, the second conductive layer may have a triple-layer structure such as titanium (Ti)/copper (Cu)/titanium (Ti).

A third insulating layer 140 may be positioned on the second conductive layer. The third insulating layer 140 may be referred to as an interlayer insulating layer. The third insulating layer 140 may be an inorganic insulating layer including an inorganic insulating material such as silicon oxide, silicon nitride, or silicon oxynitride, and may be a single layer or multiple layers.

Above the third insulating layer 140, a third conductive layer may be disposed, which may include a first gate line GL1, third capacitor electrodes C3, first connecting members CM1, second connecting members CM2, third connecting members CM3, fourth connecting members CM4, fifth connecting members CM5, etc. FIG. 10 shows the first conductive layer, the semiconductor layers, the second conductive layer, and the third conductive layer.

The first gate line GL1 may be extended in the second direction y. The first gate line GL1 may be connected to the second gate electrode G2 of the second transistor T2 and the third gate electrode G3 of the third transistor T3. The second gate line GL2 may be identical to the first gate line GL1. In this case, the first gate line GL1 may transmit the first scan signal SC as well as the second scan signal SS. The second gate line GL2 may be provided separately from the first gate line GL1.

The third capacitor electrode C3 may overlap the first capacitor electrodes C1. Accordingly, the third capacitor electrode C3 may form the second electrode of the storage capacitor CST of each pixel PXa, PXb, and PXc. By forming the first capacitor electrode C1 to overlap the second capacitor electrode C2 and forming the third capacitor electrode C3 to overlap the first capacitor electrode C1, the capacity of the storage capacitor CST may be increased.

The first connecting member CM1 may electrically connect the second region of the first semiconductor layer A1 and the light blocking layer LB.

The first connecting member CM1 may be connected to the second region of the first semiconductor layer A1 through a contact hole formed in the third insulating layer 140, and may be connected to the light blocking layer LB through contact holes formed in the first and third insulating layers 120 and 140, respectively. The first connecting member CM1 may be connected to the third capacitor electrode C3. The first connecting member CM1 and the third capacitor electrode C3 may be connected. The first connecting member CM1 and the third capacitor electrode C3 may be formed integrally.

The second connecting member CM2 may electrically connect the first region of the third semiconductor layer A3 and the initialization voltage line VL3. The third connecting member CM3 may electrically connect the first region of the first semiconductor layer A1 and the first driving voltage line VL1a. The fourth connecting member CM4 may electrically connect the second region of the corresponding second semiconductor layer A2 and the first capacitor electrode C1. The fifth connecting member CM5 may electrically connect the first region of the corresponding second semiconductor layer A2 and the data lines DLa, DLb, and DLc.

The components included in the third conductive layer may be formed using the same material in the same process. The third conductive layer may include a metal such as copper (Cu), aluminum (Al), titanium (Ti), molybdenum (Mo), or tungsten (W), and may be a single layer or multiple layers. For example, the third conductive layer may have a double-layer structure such as titanium (Ti)/copper (Cu).

A fourth insulating layer 150 may be disposed on the third conductive layer. The fourth insulating layer 150 may be referred to as a first passivation layer. The fourth insulating layer 150 may include an inorganic insulating material such as silicon nitride (SiNₓ), silicon oxide (SiOₓ), or silicon oxynitride (SiOₓN_{y}).

A fifth insulating layer 160 may be disposed on the fourth insulating layer 150.

The fifth insulating layer 160 may be referred to as a first planarizing layer. The fifth insulating layer 160 may include organic insulating materials such as a general-purpose polymer such as poly(methyl methacrylate) and polystyrene, a derivative of a polymer having a phenolic group, an acryl-based polymer, an imide-based polymer (e.g., polyimide), and a siloxane-based polymer.

Above the fifth insulating layer 160, a fourth conductive layer, which may include first common voltage lines VL2a, first connection electrodes CE1, second connection electrodes CE2, etc. may be disposed. FIG. 11 shows the first conductive layer, the semiconductor layers, the second conductive layer, the third conductive layer, and the fourth conductive layer.

The first common voltage line VL2a may transmit the common voltage EL_{VSS}. The first common voltage line VL2a may be extended in the first direction x. The first common voltage line VL2a may be connected to the common voltage transmitting line CVL in the non-display area NA.

The first connection electrode CE1 may be connected to the first connecting member CM1 through contact holes formed in the fourth and fifth insulating layers 150 and 160, respectively.

Since the first connecting member CM1 may be connected to the second region of the first semiconductor layer A1 of the first transistor T1, the first connection electrode CE1 may be electrically connected to the second region of the first semiconductor layer A1 of the first transistor T1.

The first connection electrodes CE1 may cover the entire or almost the entire first capacitor electrodes C1 of the corresponding pixels PXa, PXb, and PXc. The first connection electrode CE1 may cover more than about 90% of the planar region of the first capacitor electrode C1. Since the first capacitor electrode C1 is connected to the first gate electrode G1, the voltage of the first gate electrode G1 may fluctuate due to the coupling (a parasitic capacitance) between the first capacitor electrode C1 and other conductors (e.g., pixel electrodes of other pixels, data lines DLa, DLb, and DLc, etc.). The voltage fluctuation of the first gate electrode G1 due to the parasitic capacitance may affect the driving current output from the first transistor T1. Accordingly, the display quality may deteriorate—for example, a color difference (staining) may occur due to the increased luminance caused by the increased driving current. By shielding the first capacitor electrodes C1 of the corresponding pixels PXa, PXb, and PXc through the first connection electrodes CE1 as in the embodiment, the parasitic capacitance affecting the operation of the first transistor T1 may be reduced, thereby improving display quality.

The second connection electrode CE2 may be connected to the third connecting member CM3 through contact holes formed in the fourth and fifth insulating layers 150 and 160, respectively. Since the third connecting member CM3 may be connected to the first driving voltage line VL1a, the second connection electrode CE2 may be electrically connected to the first driving voltage line VL1a.

The components included in the fourth conductive layer may be formed using the same material in the same process. The fourth conductive layer may include a metal such as lithium (Li), calcium (Ca), aluminum (Al), silver (Ag), magnesium (Mg), or gold (Au). The third conductive layer may have a multi-layer structure—for example, a triple-layer structure such as ITO/silver (Ag)/ITO.

A sixth insulating layer 170 may be disposed on the fourth conductive layer. The sixth insulating layer 170 may be referred to as a second passivation layer. The sixth insulating layer 170 may include an inorganic insulating material such as silicon nitride (SiNₓ), silicon oxide (SiOₓ), or silicon oxynitride (SiOₓN_{y}).

A seventh insulating layer 180 may be disposed on the sixth insulating layer 170. The seventh insulating layer 180 may be referred to as a second planarizing layer. The seventh insulating layer 180 may include organic insulating materials such as common polymers such as polymethyl methacrylate and polystyrene, polymer derivatives having phenolic groups, acryl-based polymers, imide polymers (e.g., polyimide), and siloxane polymers.

On the seventh insulating layer 180, a fifth conductive layer may be disposed, which may include pixel electrodes E1a, E1b, and E1c of the light emitting element ED, a second driving voltage line VL1b, a second common voltage line VL2b, a resistance reduction layer RRL, and third connection electrodes CE3. FIG. 12 shows the first conductive layer, the semiconductor layer, the second conductive layer, the third conductive layer, the fourth conductive layer, and the fifth conductive layer.

The pixel electrodes E1a, E1b, and E1e may include a first pixel electrode Ela which is the first electrode of the first pixel PXa, a second pixel electrode E1b which is the first electrode of the second pixel PXb, and a third pixel electrode E1c which is the first electrode of the third pixel PXc. Each pixel electrode E1a, E1b, and E1c may be connected to the corresponding first connection electrode CE1 through contact holes formed in the sixth and seventh insulating layers 170 and 180, respectively. Since the first connection electrode CE1 may be electrically connected to the second region of the first semiconductor layer A1 of the first transistor T1, each pixel electrode E1a, E1b, and E1c may be connected to the second region of the first semiconductor layer A1 of the corresponding first transistor T1.

The second driving voltage line VL1b may transmit the driving voltage EL_{VDD}, and the second common voltage line VL2b may transmit the common voltage EL_{VSS}. The second driving voltage line VL1b and the second common voltage line VL2b may each be extended in the second direction y. The second driving voltage line VL1b may be positioned mostly in the display area DA, but some of it may be positioned in the non-display area NA. For example, a part of the second driving voltage line VL1b may be positioned in the dummy pixel region DPA. The second common voltage line VL2b may be positioned mostly in the display area DA, but some of it may be positioned in the non-display area NA. For example, a part of the second common voltage line VL2b may be positioned in the dummy pixel region DPA and extended to the resistance reduction layer RRL. The second driving voltage line VL1b and the second common voltage line VL2b may be arranged alternately along the first direction x.

The second driving voltage line VL1b may be connected to the second connection electrode CE2 through contact holes formed in the sixth and seventh insulating layers 170 and 180, respectively. Since the second connection electrode CE2 may be electrically connected to the first driving voltage line VL1a, the second driving voltage line VL1b may be electrically connected to the first driving voltage line VL1a. As the first driving voltage lines VL1a extending in the first direction x and the second driving voltage lines VL1b extending in the second direction y are connected in the display area DA, the wires transmitting the driving voltage EL_{VDD} may be provided in a mesh form in the display area DA. Accordingly, the uniform level of the driving voltage EL_{VDD} may be provided across the entire display area DA.

The second common voltage line VL2b may be connected to the first common voltage line VL2a through contact holes formed in the sixth and seventh insulating layers 170 and 180, respectively. As the first common voltage lines VL2a extending in the first direction x and the second common voltage lines VL2b extending in the second direction y are connected in the display area DA, the wires transmitting the common voltage EL_{VSS} may be provided in a mesh form in the display area DA. Accordingly, the uniform level of the common voltage EL_{VSS} may be provided across the entire display area DA.

The resistance reduction layer RRL may be positioned in the non-display area NA. The resistance reduction layer RRL may be disposed to surround at least a portion of the display area DA. For example, the resistance reduction layer RRL may be positioned at the left and right sides of the display area DA, may be positioned at the left, right, and upper sides of the display area DA, or may completely surround the display area DA. The resistance reduction layer RRL may be connected to the common voltage transmitting line CVL in the non-display area NA. The resistance reduction layer RRL may be formed with openings OPr, through which gases that may be discharged from the organic insulating layer may be released.

The resistance reduction layer RRL may be connected to the second common voltage line VL2b in the non-display area NA. The resistance reduction layer RRL and the second common voltage line VL2b may be formed integrally. The second common voltage line VL2b may extend from the resistance reduction layer RRL in the second direction y. As the resistance reduction layer RRL is connected to the second common voltage line VL2b, the resistance of the wire transmitting the common voltage EL_{VSS} may be reduced. Accordingly, a RC delay in the common voltage EL_{VSS} may be reduced, the power consumption may be reduced, and heat generating from the wire transmitting the common voltage EL_{VSS} may be reduced. In addition, since the resistance reduction layer RRL is integrally formed with the second common voltage line VL2b positioned in the display area DA, the resistance of the wire transmitting the common voltage EL_{VSS} may be reduced compared to an example in which the resistance reduction layer RRL and the second common voltage line VL2b are connected using a separate conductive material.

The third connection electrode CE3 may be connected to the first common voltage line VL2a through contact holes formed in the sixth and seventh insulating layers 170 and 180, respectively.

The components included in the fifth conductive layer may be formed using the same material in the same process. The fifth conductive layer may be formed of a reflective conductive material or a semi-transmissive conductive material, or may be also formed of a transparent conductive material. The fifth conductive layer may include a transparent conductive material such as indium tin oxide (ITO) or indium zinc oxide (IZO). The fifth conductive layer may include metals such as lithium (Li), calcium (Ca), aluminum (Al), silver (Ag), magnesium (Mg), and gold (Au). The fifth conductive layer may have a multi-layer structure for example, a triple-layer structure such as ITO/silver (Ag)/ITO.

An eighth insulating layer 190 may be disposed on the fifth conductive layer. The eighth insulating layer 190 may be referred to as a pixel defining layer. The eighth insulating layer 190 may include an organic insulating material such as an acryl-based polymer, an imide-based polymer, or an amide-based polymer. The eighth insulating layer 190 may include a black pigment. For example, the eighth insulating layer 190 may include a polyimide binder and a pigment mixture of red, green, and blue. The eighth insulating layer 190 may include a cardo-based binder resin and a mixture of lactam black pigment and blue pigment. The eighth insulating layer 190 may include a carbon black. The eighth insulating layer 190 including the black pigment may improve the contrast ratio and prevent a reflection by the metal layer positioned below.

The eighth insulating layer 190 may cover the edges of the pixel electrodes E1a, E1b, and E1c. The eighth insulating layer 190 may cover the first connection electrode CE1 and the second common voltage line VL2b. The eighth insulating layer 190 may have openings OPa, OPb, and OPc that extend to the pixel electrodes E1a, E1b, and E1c. The openings OPa, OPb, and OPc may be regions where the eighth insulating layer 190 is removed in the third direction z, which is the thickness direction. The openings OPa, OPb, and OPc may correspond to the light emitting regions EAa, EAb, and EAc of each pixel PXa, PXb, and PXc. That is, the openings OPa, OPb, and OPc may include a first opening OPa corresponding to the light emitting region EAa of the first pixel PXa, a second opening OPb corresponding to the light emitting region EAb of the second pixel PXb, and a third opening OPc corresponding to the light emitting region EAc of the third pixel PXc. One or more of the openings OPa, OPb, and OPc may be split into a plurality of parts. For example, as illustrated, each of the second and third openings OPb and OPc may be divided into two parts. The amount of light emitted from the light emitting regions EAa, EAb, and EAc of the pixels PXa, PXb, and PXc may vary depending on the area of the openings OPa, OPb, and OPc, and a color tone of the image displayed on the light emitting display device 1 may be controlled by adjusting the area of the openings OPa, OPb, and OPc.

An intermediate layer EL may be disposed on the fifth conductive layer. The intermediate layer EL may be positioned across the pixels PXa, PXb, and PXc. The intermediate layer EL may be positioned continuously across the entire display area DA. The intermediate layer EL may extend to a portion of the non-display area NA. For example, the intermediate layer EL may include a portion that overlaps a part of the resistance reduction layer RRL. The intermediate layer EL may be in contact with the pixel electrodes E1a, E1b, and E1c through the openings OPa, OPb, and OPc of the eighth insulating layer 190.

The intermediate layer EL may include a light emitting layer and a function layer. The light emitting layer is a layer in which electricity is converted into light through a combination of electrons and holes, and may include organic or inorganic materials that emit light of a predetermined color. The light emitting layer may include a light emitting material that emits blue light. The light emitting layer may include light emitting material that emits red or green light in addition to blue light. The light emitting layer may include a plurality of light emitting layers, and the plurality of light emitting layers may include light emitting layers that emit light of the same color, or may include light emitting layers that emit light of different colors. For example, the light emitting layer may have a structure in which two or three blue-light emitting layers are laminated. The function layer may include at least one of a hole injection layer (HIL), a hole transport layer (HTL), an electron transport layer (ETL), and an electron injection layer (EIL).

A common electrode E2, which is the second electrode of the light emitting element ED and may be referred to as a cathode, may be disposed on the intermediate layer EL. The common electrode E2 may be positioned across the pixels PXa, PXb, and PXc. The common electrode E2 may be deposited using an open mask, and the common electrode E2 may be positioned continuously across the entire display area DA. The common electrode E2 may extend to a portion of the non-display area NA.

The common electrode E2 may be connected to the resistance reduction layer RRL through contact holes H1 formed in the eighth insulating layer 190 in the non-display area NA or through contact holes formed in the eighth insulating layer 190 and the intermediate layer EL. The common electrode E2 may be applied with the common voltage EL_{VSS} through the resistance reduction layer RRL. The common electrode E2 may be connected to the third connection electrodes CE3 through contact holes H2 formed in the eighth insulating layer 190 and the intermediate layer EL in the display area DA. Since the third connection electrode CE3 may be connected to the first common voltage line VL2a, the common electrode E2 may be electrically connected to the first common voltage line VL2a and may receive the common voltage EL_{VSS} through the third connection electrode CE3. The common electrode E2 may be connected to the second common voltage line VL2b through contact holes formed in the eighth insulating layer 190 and the intermediate layer EL in the display area DA and may receive the common voltage EL_{VSS} through the second common voltage line VL2b. In this way, since the common electrode E2 may receive the common voltage EL_{VSS} at numerous points not only in the display area DA but also in the non-display area NA, a voltage drop (an IR drop) due to the resistance of the common electrode E2 may be ignored even if the resistance of the common electrode E2 is large. Accordingly, the common voltage EL_{VSS} may be uniformly applied to the pixels PXa, PXb, and PXc throughout the display area DA, thereby avoiding the luminance variation in the display area DA that may be caused by the voltage drop due to the resistance of the common electrode E2.

A laser drilling process may be performed to form contact holes in the intermediate layer EL and the eighth insulating layer 190 to connect the common electrode E2 to the third connection electrode CE3 and the second common voltage line VL2b. For example, after forming the intermediate layer EL, a laser may be irradiated at a position where a contact hole is to be formed to remove the intermediate layer EL and the eighth insulating layer 190, thereby forming the contact holes extending through the intermediate layer EL and the eighth insulating layer 190. Accordingly, the parts of the third connection electrodes CE3 and the second common voltage lines VL2b that overlap the contact holes may be exposed. Then, by forming the common electrode E2, the common electrode E2 may be connected to the third connection electrodes CE3 and the second common voltage lines VL2b through the contact holes. By forming the contact hole of the eighth insulating layer 190 before depositing the intermediate layer EL, a laser drilling process may be used only to form a contact hole of the intermediated layer EL that overlaps the contact hole of the eighth insulating layer 190.

The pixel electrodes E1a, E1b, and E1c, the intermediate layer EL, and the common electrode E2 may form the light emitting element ED, which may be an organic or inorganic light emitting diode. The pixel electrodes E1a, E1b, and E1c may be individually provided for each corresponding pixel PXa, PXb, and PXc to receive the driving current. The common electrode E2 is provided commonly to the pixels PXa, PXb, and PXc, thereby receiving a common voltage. The pixel electrodes E1a, E1b, and E1c may be anodes, which are hole injection electrodes, and the common electrode E2 may be a cathode, which is an electron injection electrode. Conversely, the pixel electrodes E1a, E1b, and E1c may be cathodes and the common electrode E2 may be an anode. The openings OPa, OPb, and OPc of the eighth insulating layer 190 may correspond to the light emitting regions EAa, EAb, and EAc of the light emitting element ED.

An encapsulation layer TFE may be disposed on the common electrode E2. The encapsulating layer TFE may seal the light emitting elements ED and prevent moisture or oxygen from penetrating into the light emitting elements ED from outside. The encapsulation layer TFE covers the entire display area DA, and the edge of the encapsulation layer TFE may be positioned in the non-display area NA.

The encapsulation layer TFE may be a thin-film encapsulation layer that may include a first inorganic layer IL1, an organic layer OL, and a second inorganic layer IL2. The first and second inorganic layers IL1 and IL2 may mainly prevent the penetration of moisture, etc., and the organic layer OL may mainly planarize the surface of the encapsulation layer TFE, particularly the surface of the second inorganic layer IL2 in the display area DA. The first and second inorganic layers IL1 and IL2 may include inorganic insulating materials such as silicon oxide or silicon nitride. The organic layer OL may include organic materials such as acryl-based resin, methacryl-based resin, polyisoprene, vinyl-based resin, epoxy-based resin, urethane-based resin, cellulose-based resin, or perylene-based resin.

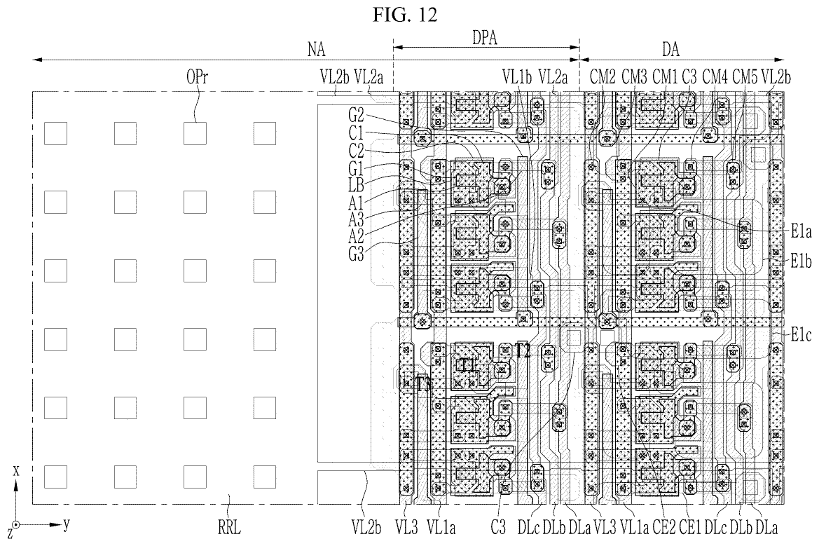

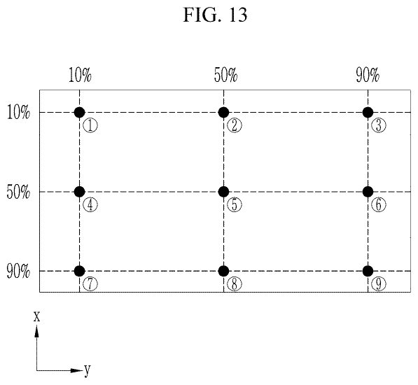

FIG. 13 is a diagram showing a measurement position of a voltage drop in the light emitting display device according to an embodiment and a comparative example.

FIG. 13 shows the positions where the voltage drop of the common voltage EL_{VSS} is measured in the display device according to an embodiment and in the display device according to the comparative example. The region shown in FIG. 13 represents the display area DA, and 10%, 50%, and 90% indicate the relative positions in the horizontal and vertical directions with respect to the left and top ends of the display area DA. In the comparative example, unlike the aforementioned embodiment, the resistance reduction layer RRL is not connected to the second common voltage line VL2b, but only connected to the common electrode E2.

For each of the display device according to the embodiment and the display device according to the comparative example, the common voltage EL_{VSS} was measured at the nine positions shown in FIG. 12. The difference between the common voltage EL_{VSS} output from the driver IC chip 30 and the measured common voltage EL_{VSS} (the IR drop of the common voltage EL_{VSS}) is shown in the following Table 1.

TABLE 1

| | EL_{VSS} IR Drop [V] | | |
|---|---|---|---|
| Embodiment | [symbol] 0.252 | [symbol] 0.376 | [symbol] 0.256 |
| | [symbol] 0.423 | [symbol] 0.488 | [symbol] 0.427 |
| | [symbol] 0.250 | [symbol] 0.388 | [symbol] 0.254 |
| Comparative | [symbol] 0.294 | [symbol] 0.416 | [symbol] 0.295 |
| example | [symbol] 0.531 | [symbol] 0.569 | [symbol] 0.531 |
| | [symbol] 0.287 | [symbol] 0.427 | [symbol] 0.288 |
| ID Drop | [symbol] 0.042 | [symbol] 0.040 | [symbol] 0.039 |
| improvement | [symbol] 0.108 | [symbol] 0.081 | [symbol] 0.104 |
| effect [ΔV] | [symbol] 0.037 | [symbol] 0.039 | [symbol] 0.034 |

The display device according to the embodiment shows improved voltage drop in all measured positions compared to the display device according to the comparative example. In particular, at the measurement positions \textcircled{4}, \textcircled{5}, and \textcircled{6} which are arranged in the center of the display area DA along the horizontal direction, the voltage drop was found to be improved by more than twice compared to other points.

FIG. 14 is a schematic cross-sectional view of a display area in a light emitting display device according to an embodiment. Referring to FIG. 14, the display panel 10 may include a display unit 100, a color conversion unit 200, and a filler 400 disposed between the display unit 100 and the color conversion unit 200.

The display unit 100 may include a substrate 110, a transistor TR formed on the substrate 110, and a light emitting element ED connected to the transistor TR. The light emitting element ED may be an organic or inorganic light emitting diode. The light emitting element ED may be a micro-light emitting diode. The transistor TR may include a semiconductor layer AL, a gate electrode GE, a first electrode DE, and a second electrode SE. The first electrode DE may be connected to the first region of the semiconductor layer AL. The second electrode SE (corresponding to the first connecting member CM1 in the above-described embodiment) may be connected to the second region of the semiconductor layer AL and the light blocking layer LB. The illustrated transistor TR may be the first transistor T1. Since the display unit 100 has been described in detail above, the color conversion unit 200 and the filler 400 will be described in detail here.

The color conversion unit 200 may be disposed on the encapsulation layer TFE of the display unit 100.

The color conversion unit 200 may include a substrate 210. The substrate 210 may include an insulating material such as glass or plastic—for example, the substrate 110 may be a glass substrate.

In the direction toward the display unit 100, color filters 230a, 230b, and 230c may be disposed on the substrate 210. In the display area DA, the color filters 230a, 230b, and 230c may be formed in regions corresponding to the openings OPa, OPb, and OPc of the eighth insulating layer 190. The color filters 230a, 230b, and 230c may include a first color filter 230a that transmits light of a first wavelength and absorbs light of the remaining wavelengths, a second color filter 230b that transmits light of a second wavelength and absorbs light of the remaining wavelengths, and a third color filter 230c that transmits light of a third wavelength and absorbs light of the remaining wavelengths. The first color filter 230a, the second color filter 230b, and the third color filter 230c may overlap the first pixel PXa, the second pixel PXb, and the third pixel PXc, respectively. Accordingly, the purity of the first wavelength light (corresponding to the first pixel PXa), the second wavelength light (corresponding to the second pixel PXb), and the third wavelength light (corresponding to the third pixel PXc) emitted outside the display panel 10 may be increased. The light of the first wavelength, the light of the second wavelength, and the light of the third wavelength may be a red light, a green light, and a blue light, respectively.

At the boundaries of the pixels PXa, PXb, and PXc, the first color filter 230a, the second color filter 230b, and the third color filter 230c overlap each other to form a light-blocking region. As illustrated, the light-blocking region may include the first color filter 230a, the second color filter 230b, and the third color filter 230c that are overlapped with each other in the thickness direction, but only two color filters overlapped with each other may form the light-blocking region. For example, the first color filter 230a and the second color filter 230b may overlap at the boundary between the first pixel PXa and the second pixel PXb, the second color filter 230b and the third color filter 230c may overlap at the boundary between the second pixel PXb and the third pixel PXc, and the third color filter 230c and the first color filter 230a may overlap at the boundary between the third pixel PXc and the first pixel PXa to form the light-blocking region. In the non-display area NA, the first color filter 230a, the second color filter 230b, and the third color filter 230c may be disposed to form the light-blocking region. The third color filter 230c, the first color filter 230a, and the second color filter 230b are stacked in order on the substrate 210, but the present disclosure is not limited thereto. Instead of overlapping the color filters 230a, 230b, and 230c, a light blocking member may be disposed on the substrate 210 to form the light-blocking region.

A low-refractive index layer 240 may be disposed on color filters 230a, 230b, and 230c. The low-refractive index layer 240 may cover the entire substrate 210. The low-refractive index layer 240 may include an organic or inorganic material having a low-refractive index. The refractive index of the low-refractive index layer 240 may be about 1.1 to about 1.3. The low-refractive index layer 240 may be placed in a different position than as shown in FIG. 14. For example, the low-refractive index layer 240 may be positioned between the a layer including color conversion layers 270a, 270b and a transparent layer 270c, and the second capping layer 280. The color conversion unit 200 may include a plurality of low-refractive index layers. For example, the color conversion unit 200 may further include, in addition to a first low-refractive index layer 240 disposed between the color filters 230a, 230b, and 230c and the first capping layer 250 as illustrated, a second low-refractive index layer disposed between the layer including the color conversion layers 270a, and 270b and the transparent layer 270c, and the second capping layer 280.

The first capping layer 250 may be disposed on the low-refractive index layer 240. The first capping layer 250 may entirely cover the low-refractive index layer 240 to protect the low-refractive index layer 240. The first capping layer 250 may include an inorganic insulating material such as silicon oxide, silicon nitride, or silicon oxynitride, and may be a single layer or multiple layers.

A bank 260 may be disposed on the first capping layer 250. The bank 260 may be positioned in the display area DA and overlap the eighth insulating layer 190. The bank 260 may overlap the light-blocking region where the first color filter 230a, the second color filter 230b, and the third color filter 230c are overlapped. The bank 260 may be positioned at the boundaries of the pixels PXa, PXb, and PXc. The bank 260 may partition the pixel area. The bank 260 may include organic insulating materials such as acryl-based polymer, imide-based polymer, or amide-based polymer. The bank 260 may be a black bank including a colored pigment such as black pigment, but may also be transparent.

The first color conversion layer 270a, the second color conversion layer 270b, and the transparent layer 270c may be disposed on the first capping layer 250. The first color conversion layer 270a, the second color conversion layer 270b, and the transparent layer 270c may be accommodated in a space between adjacent banks 260 (i.e., the opening of the bank 260). The first color conversion layer 270a, the second color conversion layer 270b, and the transparent layer 270c may be partitioned or separated by the bank 260. The first color conversion layer 270a, the second color conversion layer 270b, and the transparent layer 270c may be accommodated using an inkjet printing process.

The first color conversion layer 270a may overlap the first color filter 230a. The first color conversion layer 270a may overlap the light emitting diode (LED) corresponding to the first pixel PXa, and may convert light incident from the light emitting diode (LED) into light of the first wavelength. The light of the first wavelength may be red light having a wavelength in a range from about 600 nm to about 650 nm—for example, about 620 nm to about 650 nm.

The second color conversion layer 270b may overlap the second color filter 230b. The second color conversion layer 270b may overlap the light emitting diode (LED) corresponding to the second pixel PXb and convert light incident from the light emitting diode (LED) into light of the second wavelength. The light of the second wavelength may be green light having a wavelength in a range from about 500 nm to about 550 nm—for example, about 510 nm to about 550 nm.

The transparent layer 270c may overlap the third color filter 230c. The transparent layer 270c may overlap the light emitting diode (LED) corresponding to the third pixel PXc and transmit light incident from the light emitting diode (LED). Light passing through the transparent layer 270c may be light of the third wavelength. The light of the third wavelength may be blue light having a wavelength in a range from about 380 nm to about 480 nm—for example, about 420 nm or more, about 430 nm or more, about 440 nm or more, or about 445 nm or more, and about 470 nm or less, about 460 nm or less, or about 455 nm or less.

The first color conversion layer 270a may include first quantum dots and the second color conversion layer 270b may include second quantum dots. For example, light incident on the first color conversion layer 270a may be converted into light of the first wavelength by the first quantum dots and be emitted. Light incident on the second color conversion layer 270b may be converted into light of the second wavelength by the second quantum dots and be emitted. Each of the first color conversion layer 270a, the second color conversion layer 270b and the transparent layer 270c may include scatterers. The scatterers may improve optical efficiency by scattering light incident on the first color conversion layer 270a, the second color conversion layer 270b, and the transparent layer 270c.

Each of the first quantum dots and the second quantum dots (hereinafter, the quantum dot is referred to as a semiconductor nanocrystal) may independently include a Group II-VI compound, a Group III-V compound, a Group IV-VI compound, a Group IV element or compound, a Group I-III-VI compound, a Group II-III-VI compound, a Group I-II-IV-VI compound, or combinations thereof.

The Group II-VI compound may be selected from a group including a binary compound selected from a group consisting of CdSe, CdTe, ZnS, ZnSe, ZnTe, ZnO, HgS, HgSe, HgTe, MgSe, MgS, and a mixture thereof, a ternary compound selected from a group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI compound may further include a Group III metal.

The Group III-V compound may be selected from a group including a binary compound selected from a group consisting of GaN, GaP, GaAs, GaSb, AlN, AlP, AlAs, AlSb, InN, InP, InAs, InSb, and a mixture thereof, a ternary compound selected from a group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a mixture thereof, and a quaternary compound selected from a group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The Group III-V compound may further include a Group II metal (e.g., InZnP).

The Group IV-VI compound may be selected from a group including a binary compound selected from a group consisting of SnS, SnSe, SnTe, PbS, PbSe, PbTe, and a mixture thereof, a ternary compound selected from a group consisting of SnSeS, SnSeTe, SnSTe, PbSeS, PbSeTe, PbSTe, SnPbS, SnPbSe, SnPbTe, and a mixture thereof, and a quaternary compound selected from a group consisting of SnPbSSe, SnPbSeTe, SnPbSTe, and a mixture thereof.

The Group IV element or compound may be selected from a group including a single element compound selected from a group consisting of Si, Ge, and combinations thereof, and a binary element compound selected from a group consisting of SiC, SiGe, and combinations thereof.

The Group I-III-VI compound may be selected from a group including CuInSe2, CuInS2, CuInGaSe, and CuInGaS, but the present disclosure is not limited thereto.

The Group II-III-VI compound may be selected from a group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combinations thereof.

The Group I-II-IV-VI compound may be selected from a group consisting of CuZnSnSe and CuZnSnS.

The quantum dot may not include cadmium. The quantum dots may include a semiconductor nanocrystal based on a Group III-V compound including indium and phosphorus. The Group III-V compound may further include zinc. The quantum dots may include a semiconductor nanocrystal based on a Group II-VI compound including a chalcogen element (e.g., sulfur, selenium, tellurium, or combinations thereof) and zinc.

In the quantum dots, the binary compound, the ternary compound, or the quaternary compound as described above may be present in the particle at a uniform concentration or in the same particle with a partially different concentration distribution. Also, they may have a core/shell structure in which one quantum dot surrounds another quantum dot. The interface between the core and the shell may have a concentration gradient in which the concentration of the elements present in the shell decreases toward the center.

In some embodiments, the quantum dot may have a core-shell structure including a core including the above-described nanocrystal and a shell surrounding the core. The shell of the quantum dot may act as a protective layer for maintaining the semiconductor characteristic by preventing a chemical modification of the core and/or a charging layer for imparting an electrophoretic characteristic to the quantum dot. The shell may be single-layered or multi-layered. The interface between the core and the shell may have a concentration gradient in which the concentration of elements present in the shell decreases toward the center. Examples of the shell of the quantum dot include a metal or non-metal oxide, a semiconductor compound, or a combination thereof.

For example, the metal or non-metal oxide may be exemplified as a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and NiO, or a ternary compound such as MgAl₂O₄, CoFe₂O₄, NiFe₂O₄, and CoMn₂O₄.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like.

The quantum dots may have a full width at half maximum (FWHM) of about 45 nm or less, preferably about 40 nm or less, or more preferably about 30 nm or less, and may improve color purity or color reproducibility in this range. Also, since light emitted through the quantum dots is emitted in all directions, a viewing angle may be widened.

In the quantum dots, the shell material and the core material may have different energy bandgaps. For example, the energy bandgap of the shell material may be greater or smaller than that of the core material. The quantum dots may have a multi-layered shell. In the multi-layered shell, the energy bandgap of the outer layer may be greater than the energy bandgap of the inner layer (i.e., the layer nearer to the core). In the multi-layered shell, the energy bandgap of the outer layer may be less than the energy bandgap of the inner layer.

The shape of the quantum dot is not especially limited. For example, the shape of the quantum dot may include a sphere, a polyhedron, a pyramid, a multi-pod, a square, a cuboid, a nanotube, a nanorod, a nanowire, a nanosheet, or a combination thereof.

The quantum dots may include an organic ligand (e.g., having a hydrophobic moiety). The organic ligand moiety may be bound to surfaces of the quantum dots. The organic ligand moiety may include RCOOH, RNH₂, R₂NH, R₃N, RSH, R₃PO, R₃P, ROH, RCOOR, RPO(OH)₂, RHPOOH, R₂POOH, or combinations thereof. Herein, R is independently a C3 to C40 substituted or unsubstituted aliphatic hydrocarbon group such as a C3 to C40 (e.g., C5 or greater and C24 or smaller) substituted or unsubstituted alkyl, or a substituted or unsubstituted alkenyl, a C6 to C40 (e.g., C6 or greater and C20 or smaller) substituted or unsubstituted aromatic hydrocarbon group such as a substituted or unsubstituted C6 to C40 aryl group, or a combination thereof.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octyl phosphine, dioctyl phosphine, tributyl phosphine, or trioctyl phosphine; a phosphine compound or an oxide compound thereof such methyl phosphine oxide, ethyl phosphine oxide, propyl phosphine oxide, butyl phosphine oxide pentyl phosphine oxide, tributyl phosphine oxide, octyl phosphine oxide, dioctyl phosphine oxide, or trioctyl phosphine oxide; a diphenyl phosphine, a triphenyl phosphine compound, or an oxide compound thereof; and a C5 to C20 alkyl phosphonic acid such as hexyl phosphinic acid, octyl phosphinic acid, dodecane phosphinic acid, tetradecane phosphinic acid, hexadecane phosphinic acid, or octadecane phosphinic acid. The quantum dots may include a hydrophobic organic ligand alone or a mixture of at least two types. The hydrophobic organic ligand may not include a photopolymerizable moiety (e.g., an acrylate group, a methacrylate group, etc.).

A second capping layer 280 may be disposed on the bank 260. The second capping layer 280 may entirely cover the substrate 210. The second capping layer 280 may cover the first color conversion layer 270a, the second color conversion layer 270b, and the transparent layer 270c. The second capping layer 280 may include an inorganic insulating material such as silicon oxide, silicon nitride, or silicon oxynitride, and may be a single layer or multiple layers.

The low-refractive index layer 240, the first capping layer 250, and the second capping layer 280 may cover the sides of the color filters 230a, 230b, and 230c at the edge of the color conversion unit 200. The low-refractive index layer 240, the first capping layer 250, and the second capping layer 280 may extend to the edge of the substrate 210, and the low-refractive index layer 240 may be in contact with the substrate 210 at the edge of the color conversion unit 200. The low-refractive index layer 240, the first capping layer 250, and the second capping layer 280 may form a blocking member that prevents moisture, oxygen, etc. from penetrating from the edge of the color conversion unit 200.

The filler 400 may be disposed between the color conversion unit 200 and the display unit 100. The filler 400 may fill the space between the display unit 100 and the color conversion unit 200 to increase the compression resistance between the display unit 100 and the color conversion unit 200. A first surface of the filler 400 may be in contact with the second capping layer 280, and a second surface of the filler 400 may be in contact with the encapsulating layer TFE. The filler 400 may be formed by applying a filler material on the second capping layer 280, overlapping the display unit 100, and then curing it. The filler 400 may include an organic material such as epoxy resin.

A display device according to an embodiment may be applied to various electronic devices. An electronic device according to an embodiment may include the display device, and may further include modules or devices having additional functions other than the display device.

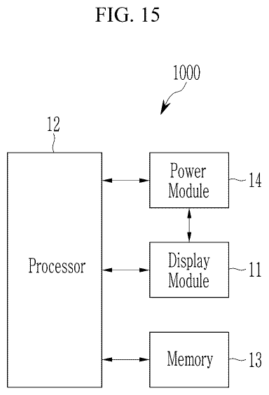

FIG. 15 is a block diagram of an electronic device according to an embodiment.

Referring to FIG. 15, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The processor 12 may provide input image data to the display device, and the display device may display an image based on the input image data.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 11 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

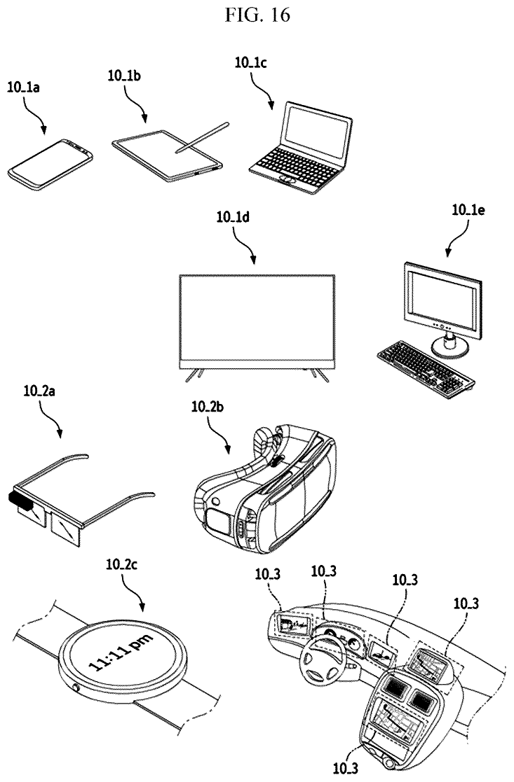

FIG. 16 shows schematic diagrams of electronic devices according to various embodiments.

Referring to FIG. 16, various electronic devices including the display device according to the embodiments may include not only image display electronic devices such as smartphones 10_1a, tablet PCs 10_1b, laptops 10_1c, TVs 10_1d, desktop monitors 10_1e, but also wearable electronic devices having display modules such as smart glasses 10_2a, head-mounted displays 10_2b, smart watches 10_2c. The electronic devices including the display device according to the embodiments may include automotive electronic devices having display modules 10_3 such as those placed on car dashboards, center fasciae, CID (Center Information Display), room mirror displays, and so on.

Although the present disclosure has been described in connection with what is presently considered to be practical embodiments, it is to be understood that the inventive concept is not limited to the disclosed embodiments. On the contrary, it is intended to cover various modifications and equivalent arrangements included within the spirit and scope of the appended claims.

What is claimed is:

1. A light emitting display device comprising:
a substrate including a display area in which pixels are arranged and a non-display area adjacent to the display area;
a first power line extending in a first direction in the display area;
a second power line extending in a second direction intersecting the first direction in the display area;
a resistance reduction layer disposed in the non-display area; and
a common electrode disposed across the display area and the non-display area, and connected to the resistance reduction layer in the non-display area,
wherein the second power line is connected to the resistance reduction layer in the non-display area and is connected to the first power line in the display area.

2. The light emitting display device of claim 1, wherein the second power line extends from the resistance reduction layer in the second direction,
wherein the common electrode is connected to the second power line in the display area, and
wherein the second power line and the resistance reduction layer are integrally formed.

3. The light emitting display device of claim 1, further comprising
an insulating layer disposed between the first power line and the second power line; and
a connection electrode disposed on the insulating layer and connected to the first power line through a contact hole formed in the insulating layer,
wherein the second power line is connected to the first power line through a contact hole formed in the insulating layer,
wherein the common electrode is connected to the connection electrode, and
wherein the insulating layer includes an inorganic insulating layer disposed on the first power line and an organic insulating layer disposed on the inorganic insulating layer.

4. The light emitting display device of claim 3, further comprising:
a pixel electrode disposed on the insulating layer,
wherein the resistance reduction layer and the second power line are disposed on a same layer as the pixel electrode.

5. The light emitting display device of claim 1, further comprising:
an insulating layer disposed on the second power line; and
an intermediate layer disposed on the insulating layer and including a light emitting layer,
wherein the common electrode is connected to the second power line through a contact hole formed in the light emitting layer and the insulating layer in the display area.

6. The light emitting display device of claim 5, wherein the common electrode is connected to the resistance reduction layer through a contact hole formed in the insulating layer in the non-display area.

7. The light emitting display device of claim 1, further comprising:
a driving voltage line extending in the second direction in the display area and transmitting the driving voltage,
wherein the driving voltage line is disposed on a same layer as the second power line, and
wherein the first power line and the second power line transmit a common voltage.

8. The light emitting display device of claim 1, wherein the non-display area includes a dummy pixel region disposed between the resistance reduction layer and the display area, and
wherein the second power line extends across the dummy pixel region in the second direction.

9. A light emitting display device comprising:
a substrate including a display area and a non-display area;
a first common voltage line extending in a first direction in the display area and transmitting a common voltage;
a second common voltage line extending in a second direction intersecting the first direction above the first common voltage line, connected to the first common voltage line, and transmitting the common voltage;
a pixel electrode disposed in the display area;
a resistance reduction layer disposed in the non-display area, disposed on a same layer as the second common voltage line, and connected to the second common voltage line; and
a common electrode disposed on the second common voltage line and the resistance reduction layer, connected to the second common voltage line in the display area, and connected to the resistance reduction layer in the non-display area.

10. The light emitting display device of claim 9, wherein the second common voltage line and the resistance reduction layer are disposed on a same layer as the pixel electrode.

11. The light emitting display device of claim 9, further comprising:
a connection electrode disposed on a same layer as the second common voltage line and overlapping the first common voltage line; and
the common electrode is connected to the first common voltage line through the connection electrode.

12. The light emitting display device of claim 9, further comprising:
a first driving voltage line extending in the first direction in the display area and transmitting a driving voltage; and
a second driving voltage line extending in the second direction above the first driving voltage line, disposed on a same layer as the second common voltage line, and transmitting the driving voltage.

13. The light emitting display device of claim 12, further comprising:
a connection electrode disposed on a same layer as the first common voltage line,
wherein the second driving voltage line is connected to the first common voltage line through the connection electrode.

14. The light emitting display device of claim 9, wherein the non-display area includes a dummy pixel region disposed between the resistance reduction layer and the display area, and
wherein the second common voltage line extends across the dummy pixel region in the second direction.

15. The light emitting display device of claim 9, further comprising:
an intermediate layer disposed between the pixel electrode and the common electrode and including a light emitting layer,
wherein the common electrode is connected to the second common voltage line through a contact hole formed in the light emitting layer.

16. An electronic device comprising:
a processor providing input image data; and
a display device displaying an image based on the input image data,
wherein the display device comprises
a substrate including a display area in which pixels are arranged and a non-display area adjacent to the display area;
a first power line extending in a first direction in the display area;
a second power line extending in a second direction intersecting the first direction in the display area;
a resistance reduction layer disposed in the non-display area; and
a common electrode disposed across the display area and the non-display area, and connected to the resistance reduction layer in the non-display area,
wherein the second power line is connected to the resistance reduction layer in the non-display area and is connected to the first power line in the display area.

17. The electronic device of claim 16, wherein the second power line extends from the resistance reduction layer in the second direction.

18. The electronic device of claim 16, wherein the common electrode is connected to the second power line in the display area.

19. The electronic device of claim 16, wherein the second power line and the resistance reduction layer are integrally formed.

20. The electronic device of claim 16, wherein the display device comprises an insulating layer disposed between the first power line and the second power line, and
wherein the second power line is connected to the first power line through a contact hole formed in the insulating layer.
